(19) United States
(12) Patent Application Publication
(10) Pub. No.: US 2026/0040990 A1
(43) Pub. Date: Feb. 5, 2026

(54) SEMICONDUCTOR PACKAGE AND METHOD OF MANUFACTURING SEMICONDUCTOR PACKAGE

(71) Applicant: SAMSUNG ELECTRONICS CO., LTD., SUWON-SI (KR)

(72) Inventors: Yuta YAMAKAWA, Yokohama (JP); Miki TAKAHASHI, Yokohama (JP)

(73) Assignee: SAMSUNG ELECTRONICS CO., LTD., SUWON-SI (KR)

(21) Appl. No.: 19/273,813

(22) Filed: Jul. 18, 2025

(30) Foreign Application Priority Data
Jul. 31, 2024 (JP) 2024-124281

(51) Int. Cl. H01L 23/31; H01L 21/304; H01L 21/56; H01L 21/683; H01L 23/00

(52) U.S. Cl. CPC H01L 23/3121; H01L 21/3043; H01L 21/56; H01L 24/16; H01L 21/6836; H01L 2221/68327; H01L 2224/16111; H01L 2224/16225

(57) ABSTRACT

Provided are a semiconductor package, in which an underfill material may enter a gap easily, and a method of manufacturing the semiconductor package. Here, the semiconductor package has a die and a plurality of pillars disposed on one surface of the die, and a thickness of the die corresponding to a region having pillars on the one surface of the die is less than a thickness of the die corresponding to a region without pillars on the one surface of the die.

### CROSS-REFERENCE TO RELATED APPLICATION

This application claims the benefits of Japanese Patent Application No. 2024-124281, filed on Jul. 31, 2024, in the Japanese Intellectual Property Office the disclosure of which is incorporated by reference herein in its entirety.

### BACKGROUND

The inventive concept relates to a semiconductor package and a method of manufacturing the semiconductor package.

As electrical appliances become more highly functional, semiconductor packages that are mounted on the electrical appliances and equipped with integrated circuits, processors, image sensors, etc. have been reduced in size and thickness. The semiconductor packages have dies that have designated circuit functions. A die has a plurality of pillars on one side and is bridge-connected to a substrate by the plurality of pillars.

However, recently, the gap between the die and the substrate has been reduced due to the reduction in the size and thickness of semiconductor packages. Furthermore, the dies also have increasing surfaces. As the gap is getting narrower and the area of the die is getting larger, it is difficult for an underfill material sealing the die to enter the gap. This may lead to a defect in sealing of the die.

In general, semiconductor packages may include an underfill composition that is intended to improve properties, such as viscosity, by adjusting the composition and content of materials in an underfill material to provide sufficient reliability to electronic components.

### SUMMARY

However, as semiconductor packages have rapidly decreased in thickness, the gap has also dramatically narrowed. As a result, even when the properties of the underfill material have been improved, there is still an issue in which the underfill material is difficult to enter the gap.

The inventive concept provides a semiconductor package having a structure of a die in which an underfill material is easy to enter a gap and a method of manufacturing the semiconductor package.

The inventive concept also provides a semiconductor package and a method of manufacturing the semiconductor package, in which, when a die that has a pillar is picked up by a collet, air leakage between the collet and the die may be prevented or suppressed.

According to an aspect of the inventive concept, there is provided a semiconductor package including a die and a plurality of pillars disposed on one surface of the die, wherein a thickness of the die corresponding to a region having the plurality of pillars on the one surface of the die is less than a thickness of the die corresponding to a region without the plurality of pillars on the one surface of the die.

In an embodiment, in a region of the one surface of the die in which the plurality of pillars are densely arranged, the die may have a smaller thickness than other regions of the one surface of the die in which the plurality of pillars are less densely arranged.

In an embodiment, the thickness of the die may change continuously along the one surface of the die according to denseness of the number of pillars on the one surface of the die.

In an embodiment, a difference between a maximum value and a minimum value of a thickness of the die may be greater than or equal to 15 μm.

In an embodiment, the die may include a bridge die configured to connect two different internal dies to each other.

In an embodiment, the semiconductor package may further include a substrate connected to the die via the plurality of pillars and a sealing member configured to seal the die above the substrate.

In an embodiment, the die may be flip-chip bonded to the substrate via the plurality of pillars.

In an embodiment, a thickness of the sealing member between the substrate and the region having the plurality of pillars on the one surface of the die may be greater than a thickness of the sealing member between the substrate and the region without the plurality of pillars on the one surface of the die.

In an embodiment, the sealing member may surround the plurality of pillars between the substrate and the die.

In an embodiment, the plurality of pillars may include a conductive material.

According to another aspect of the inventive concept, there is provided a semiconductor package including a substrate, a die including a plurality of pillars disposed on one surface thereof, the die being flip-chip bonded to the substrate via the plurality of pillars, and a sealing member configured to seal the die and the plurality of pillars above the substrate, in which a thickness of the die corresponding to a region having the plurality of pillars on the one surface of the die is less than a thickness of the die corresponding to a region without the plurality of pillars on the one surface of the die, and a thickness of the sealing member overlapping the region having the plurality of pillars on the one surface of the die is greater than a thickness of the sealing member overlapping the region without the plurality of pillars on the one surface of the die.

In an embodiment, surface roughness of the one surface of the die may be greater than surface roughness of a surface of the die opposite to the one surface of the die.

According to another aspect of the inventive concept, there is provided a method of manufacturing a semiconductor package, the method including attaching a back-grind tape to one surface of a wafer, in which a plurality of pillars are disposed on the one surface of the die, vacuum-suctioning the one surface of the wafer and fixing the wafer to a vacuum chuck, and thinning the wafer by back-grinding a surface of the wafer opposite to the one surface of the wafer.

In an embodiment, the back-grind tape may include a base material and an adhesive formed on the base material, and the base material may have a thickness of about 25 μm to about 300 μm.

In an embodiment, the back-grind tape may include a base material and an adhesive formed on the base material, and the base material may have an elastic modulus of about 0.1 GPa to about 10 GPa.

In an embodiment, the back-grind tape may include a base material and an adhesive formed on the base material, and the base material may have a softening point of about 90° C. to about 250° C.

In an embodiment, the back-grind tape may include a base material and an adhesive formed on the base material, and the adhesive may have a thickness of about 5 μm to about 100 μm.

In an embodiment, the back-grind tape may include a base material and an adhesive formed on the base material, and the adhesive may have an elastic modulus of about 10 kPa to about 1,000 kPa.

In an embodiment, the method may further include forming a sealing member by supplying an underfill material between the substrate and the wafer.

In an embodiment, in the attaching of the back-grind tape to the one surface of the wafer, in which the plurality of pillars are disposed on the one surface of the die, and a thickness of the back-grind tape attached to a region having the plurality of pillars on the one surface of the wafer may be less than a thickness of the back-grind tape attached to the region without the plurality of pillars on the one surface of the wafer.

According to still another aspect of the inventive concept, there is provided a semiconductor package including a die, and a plurality of pillars disposed on one surface of the die, in which the die includes a plurality of recesses in which the plurality of pillars are disposed, respectively.

In an embodiment, the plurality of pillars include a first group of pillars and a second group of pillars disposed in a first recess and a second recess, respectively, among the plurality of recesses.

In an embodiment, intervals of pillars included in each of the first and second groups of pillars is less than a distance between the first and second groups of pillars.

In an embodiment, within a group of pillars disposed in one of the plurality of recesses, intervals of pillars in some regions differ from intervals of pillars in other regions.

In an embodiment,

In an embodiment, in a region of the one surface of the die in which the plurality of pillars are densely arranged, the die has a smaller thickness than other regions of the one surface of the die in which the plurality of pillars are less densely arranged.

### BRIEF DESCRIPTION OF THE DRAWINGS

Embodiments will be more clearly understood from the following detailed description taken in conjunction with the accompanying drawings in which:

FIG. 1 is a schematic cross-sectional view illustrating components of a semiconductor package according to a first embodiment;

FIG. 2 is a flowchart schematically illustrating a method of manufacturing the semiconductor package shown in FIG. 1;

FIG. 3 is a schematic view illustrating a process of attaching a back-grind tape to one surface of a wafer in the method of manufacturing the semiconductor package shown in FIG. 2;

FIG. 4 is a schematic view illustrating a state in which the back-grind tape is attached to the wafer in the method of manufacturing the semiconductor package shown in FIG. 2;

FIG. 5 is a schematic view illustrating a process of fixing the wafer to a vacuum chuck in the method of manufacturing the semiconductor package shown in FIG. 2;

FIG. 6 is a schematic view illustrating a state in which the wafer is fixed to the vacuum chuck in the method of manufacturing the semiconductor package shown in FIG. 2;

FIG. 7 is a schematic view illustrating a process of back-grinding the wafer in the method of manufacturing the semiconductor package shown in FIG. 2;

FIG. 8 is a schematic view illustrating the wafer that has been back-ground in the method of manufacturing the semiconductor package shown in FIG. 2;

FIG. 9 is a schematic view illustrating the wafer from which the vacuum chuck has been removed in the method of manufacturing the semiconductor package shown in FIG. 2;

FIG. 10 is a schematic view illustrating a method of sealing a die in the method of manufacturing the semiconductor package shown in FIG. 2;

FIG. 11 is a schematic view illustrating a subsequent process to that of FIG. 10;

FIG. 12 is a schematic view illustrating a subsequent process to that of FIG. 11;

FIG. 13 is a schematic view illustrating a method of sealing a die in a method of manufacturing a semiconductor package, according to the related art, as a comparative example;

FIG. 14 is a schematic view illustrating a subsequent process to that of FIG. 13;

FIG. 15 is a schematic view illustrating a subsequent process to that of FIG. 14;

FIG. 16 is a schematic view illustrating a process of picking up a die, according to a second embodiment;

FIG. 17 is a schematic view illustrating a subsequent process to that of FIG. 16;

FIG. 18 is a schematic view illustrating a subsequent process to that of FIG. 17;

FIG. 19 is a schematic view illustrating a pick-up process when using a die according to the related art, as a comparative example;

FIG. 20 is a schematic view illustrating a subsequent process to that of FIG. 19;

FIG. 21 is a schematic view illustrating a subsequent process to that of FIG. 20; and

FIG. 22 is a schematic view showing an example of manufacturing a die, according to the inventive concept.

### DETAILED DESCRIPTION OF THE EMBODIMENTS

Hereinafter, embodiments are described in detail with reference to the accompanying drawings. In the following drawings, the same reference numerals refer to the same components, and the size of each of components in the drawings may be exaggerated for clarity and convenience of description. Also, embodiments described below are only examples, and thus, various changes may be made from the embodiments.

Hereinafter, when an element is referred to as being “above” or “on” another element, not only may the element be directly above and in contact with another element, but also the element may be above but not in contact with another element.

The singular forms include the plural forms as well, unless the context clearly indicates otherwise. In addition, when it is described that a part “includes” or “has” a certain component, this indicates that the part may further include other components, rather than excluding other components, unless specifically stated to the contrary.

The use of the term “the” and other demonstratives similar thereto may correspond to both a singular form and a plural form.

Unless the order of operations constituting a method is explicitly stated or otherwise indicated, the operations are to be performed in any suitable order. The method is not necessarily limited to the order of operations described above. All examples or illustrative terms (“for example,” etc.) are only used to explain the technical idea, and the scope of the inventive concept is not limited by these examples or illustrative terms unless otherwise limited by the claims.

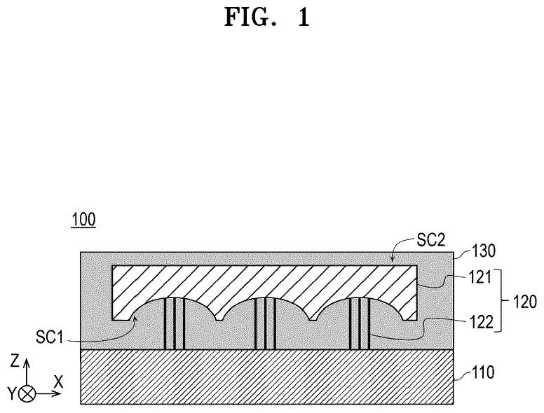

FIG. 1 is a schematic cross-sectional view illustrating components of a semiconductor package 100 according to a first embodiment. The semiconductor package 100 according to the embodiment may include, for example, a substrate 110, a die 120, and a sealing member 130 as main members thereof. Hereinafter, a direction in which the substrate 110 and a die body 121 are stacked is defined as a Z direction, a direction perpendicular to the Z direction is defined as an X direction, and a direction perpendicular to both the Z direction and the X direction is defined as a Y direction.

The substrate 110 may include a base material, such as glass, metal, or resin. The substrate 110 may include, for example, a resin substrate in which a redistribution layer (RDL) that has a large area is formed. The thickness of the substrate 110 may be, for example, about 5 μm to about 1,000 μm.

The die 120 has the die body 121 and a pillar 122. The die body 121 may include, for example, a die having a certain function. The die body 121 may include, for example, a bridge die that connects dies, such as application specific integrated circuits (ASICs), memory, or processors, to each other. Alternatively, the die body 121 may include a die that includes a passive element, an active element, an integrated circuit, a memory, etc.

Also, the die body 121 may have a multi-layered wiring layer. On the uppermost layer of the multi-layered wiring layer, electrode pads are respectively connected to multi-layered wires, and a protective insulating layer is formed. The electrode pad is formed by partially exposing the protective insulating layer. Metal, such as aluminum (Al), may be used as the material for the electrode pad. The electrode pad corresponding to a wire of each of the multi-layered wires is connected to the pillar 122. The die body 121 is flip-chip mounted on the substrate 110. The die body 121 is approximately parallel to the X-Y plane.

A plurality of pillars 122 having conductivity are disposed on one surface (hereinafter referred to as a “first surface SC1”) of the die body 121, which faces the substrate 110. Metal, such as copper (Cu), may be used as the material for the pillar 122. The size of the pillar 122 may be, for example, 30 μm in diameter and 30 μm in length. The die body 121 is bridge-connected to the substrate 110 via the pillar 122. The pillars 122 may be arranged entirely or partially on the first surface SC1 of the die body 121. In addition, the number of pillars 122 installed per unit area on the first surface SC1 of the die body 121 may vary depending on the position of the pillar 122 on the first surface SC1. That is, the arrangement intervals (pitches) of the pillars 122 in some regions on the first surface SC1 may differ from the arrangement intervals of the pillars 122 in the other regions.

In addition, in the embodiment, the thickness of the die body 121 corresponding to the region having the pillars 122 on the first surface SC1 is less than the thickness of the die body 121 corresponding to the region having no pillars 122 on the first surface SC1. More specifically, in a region in which a number of pillars 122 are densely arranged on the first surface SC1 of the die body 121, the die body 121 has a smaller thickness that a region where a number of pillars 122 are less densely arranged. The difference between the maximum value and the minimum value of the thickness of the die body 121 is preferably 15 μm or more. This is because, when the difference between the maximum value and the minimum value is 15 μm or more, the underfill material sufficiently permeates the gap between the substrate 110 and the die body 121, but when less than 15 μm, the underfill material may not sufficiently permeate the gap therebetween.

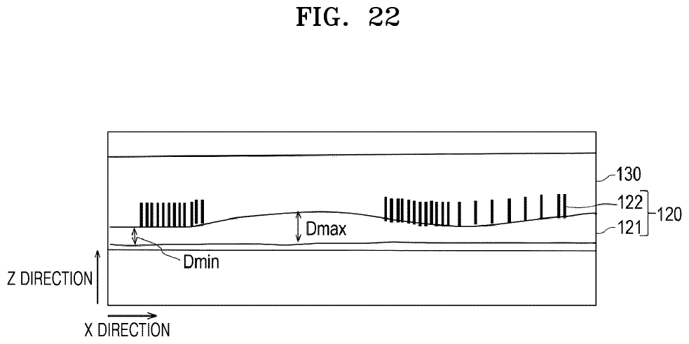

In addition, the thickness of the die body 121 may vary smoothly and continuously along the first surface SC1 depending on sparseness and denseness of the number of pillars 122 on the first surface SC1. FIG. 1 shows an enlarged and exaggerated shape of the die body 121 in the X-Z cross-section for convenience of illustration. The actual shape of the die body 121 in the X-Z cross-section or the Y-Z cross-section may be a smooth concave or convex shape (see FIG. 22), rather than a pointed concave or convex shape as shown in FIG. 1.

Relatively, the surface roughness of a second surface SC2 of the die body 121 may be less than the surface roughness of the first surface SC1 thereof.

The sealing member 130 seals the die 120 on the substrate 110. The sealing member 130 includes a resin material as an underfill material. The underfill material may include, for example, epoxy resin.

A semiconductor manufacturing apparatus according to the embodiment includes at least a first attachment device, a suction device, a polishing device, a second attachment device, a dicing device, and a sealing device (not all shown). The first attachment device attaches a back-grind tape onto a wafer 123. The back-grind tape protects the surface of the wafer 123 when polishing (back-grinding) the back side of the wafer 123. The suction device suctions the wafer 123, to which the back-grind tape has been attached, by using a vacuum chuck, and then conveys the wafer 123 to the polishing device. The polishing device polishes the back side of the wafer 123 by using a grinding wheel, thereby thinning the wafer 123. The second attachment device attaches a dicing tape onto the wafer 123. The dicing tape is used to fix the wafer 123 when dicing the wafer 123 by using the dicing device, i.e., when cutting an integrated circuit of the wafer 123 or the like into dies. The wafer 123 moves to the dicing device after the back-grind tape is detached. The dicing device cuts the integrated circuit of the wafer 123 or the like into dies. The sealing device seals the die 120 disposed on the substrate 110.

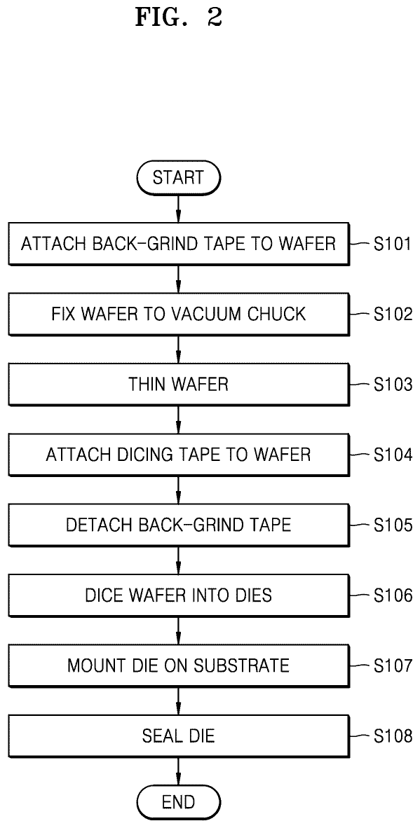

Hereinafter, with reference to FIGS. 2 to 12, a method of manufacturing the semiconductor package 100 by face-down mounting of a die, according to the embodiment, is described in detail.

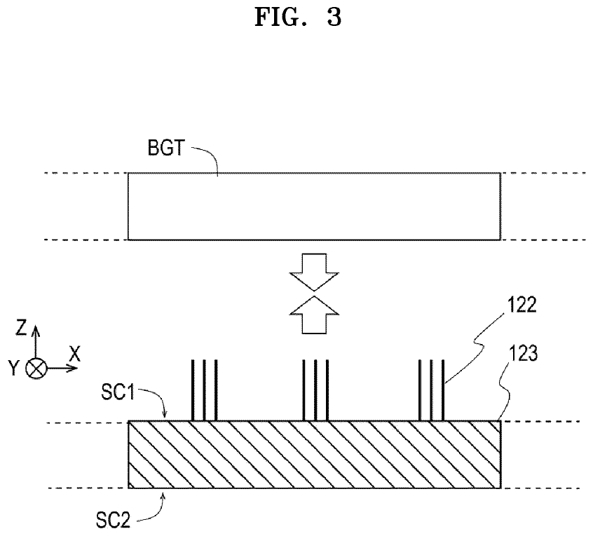

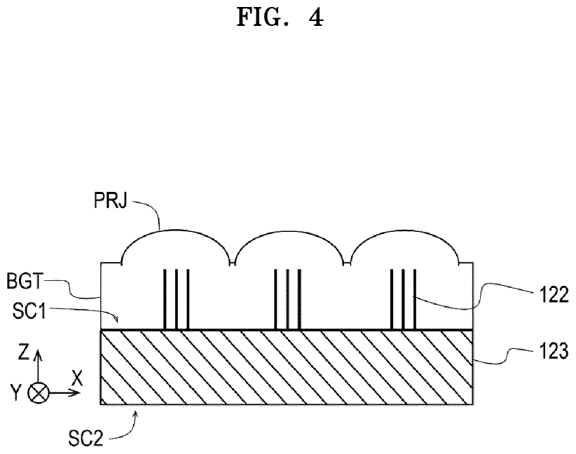

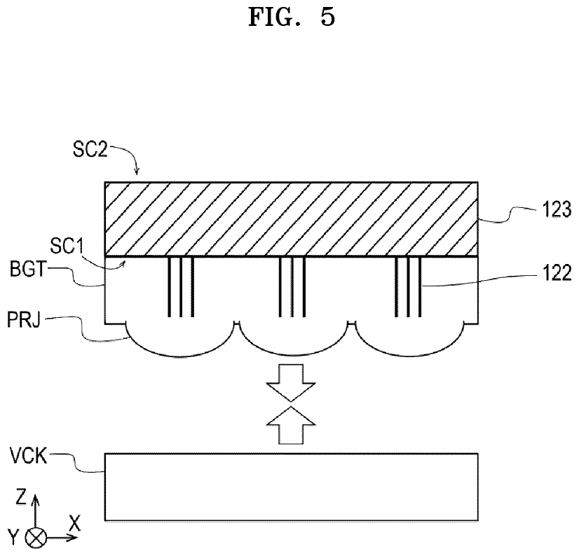

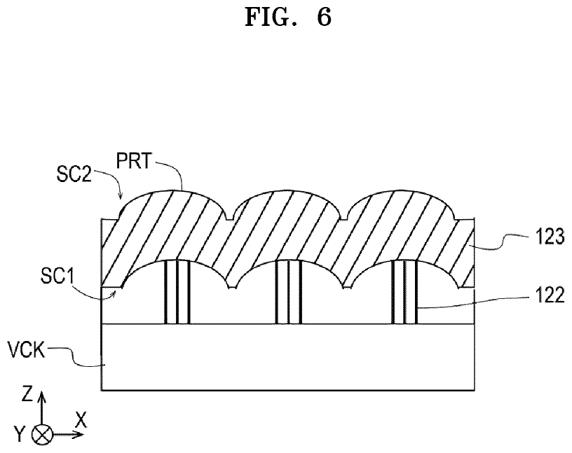

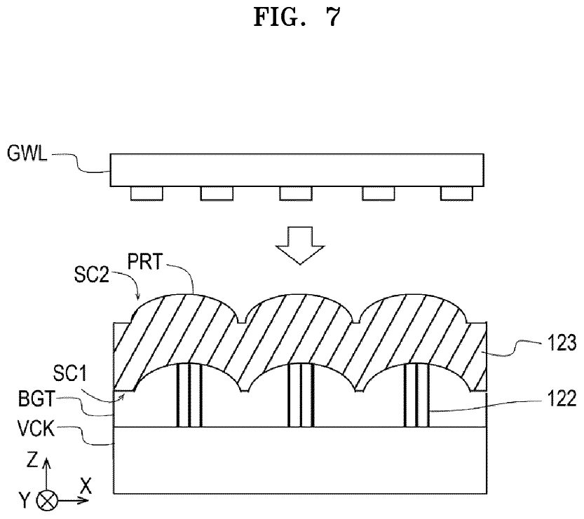

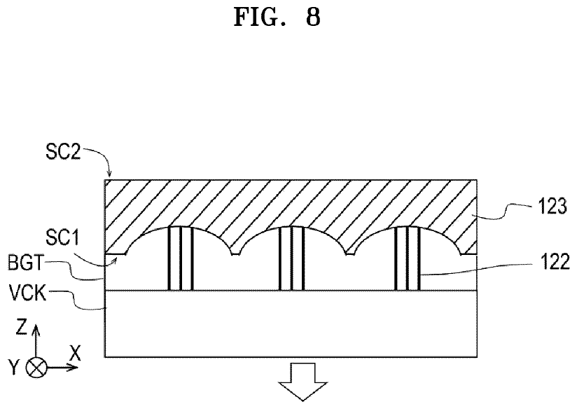

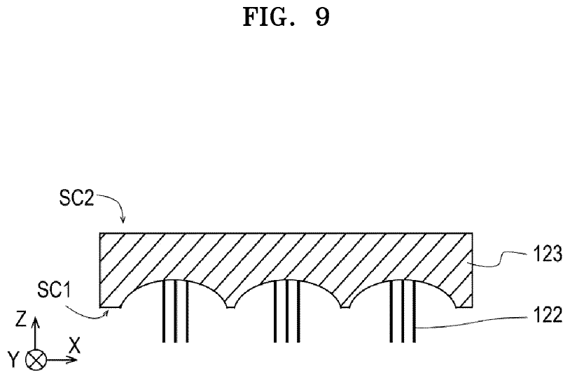

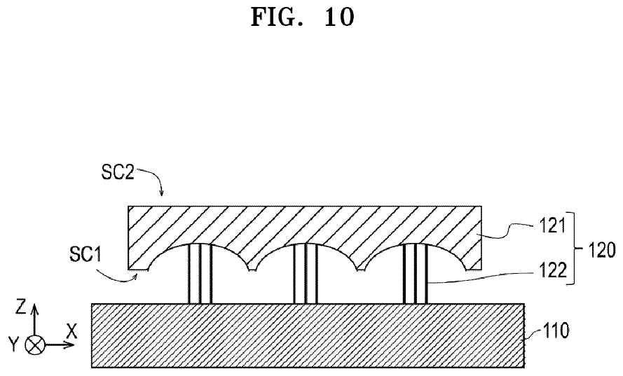

FIG. 2 is a flowchart schematically illustrating the method of manufacturing the semiconductor package shown in FIG. 1. FIG. 3 is a schematic view illustrating a process of attaching a back-grind tape to one surface of a wafer in the method of manufacturing the semiconductor package shown in FIG. 2, and FIG. 4 is a schematic view illustrating a state in which the back-grind tape is attached to the wafer. Also, FIG. 3 shows a cross-section of a portion (a solid line portion) of the wafer corresponding to the die and the remaining portion (a dashed line portion) of the wafer (FIGS. 4 to 21 show only a portion of the wafer corresponding to the die). Also, FIG. 5 is a schematic view illustrating a process of fixing the wafer to a vacuum chuck in the method of manufacturing the semiconductor package shown in FIG. 2, and FIG. 6 is a schematic view illustrating a state in which the wafer is fixed to the vacuum chuck. Also, FIG. 7 is a schematic view illustrating a process of back-grinding the wafer in the method of manufacturing the semiconductor package shown in FIG. 2, and FIG. 8 is a schematic view illustrating the wafer that has been back-ground. Also, FIG. 9 is a schematic view illustrating the wafer from which the vacuum chuck has been removed in the method of manufacturing the semiconductor package shown in FIG. 2. Also, FIGS. 10 to 12 are schematic views illustrating a method of sealing the die in the method of manufacturing the semiconductor package.

As shown in FIG. 2, first, in operation S101, the first attachment device attaches the back-grind tape onto the wafer 123. More specifically, as shown in FIG. 3, the first attachment device prepares the wafer 123 and presses and attaches a back-grind tape BGT to the first surface SC1 of the wafer 123. The initial thickness of the wafer 123 is, for example, about 500 μm to about 775 μm. As described above, the pillar 122, which has been grown by known plating processing techniques, is formed on the wafer 123. The back-grind tape BGT is used to protect a circuit on the first surface SC1 of the wafer 123 when the back side (the second surface SC2) of the wafer 123, opposite to the first surface SC1, is ground in operation S103 described below.

The back-grind tape BGT has a base material and an adhesive (a bonding layer) formed on the base material. The base material and the adhesive preferably satisfy the following conditions.

The base material may have a thickness of, for example, about 25 μm to about 300 μm, and an elastic modulus of, for example, about 0.1 GPa to about 10 GPa. Also, a softening point of the base material may be, for example, about 90° C. to about 250° C. As described above, the base material is made thin, with the thickness of about 25 μm to about 300 μm, and the base material is made hard (with the clastic modulus of about 0.1 GPa to about 10 GPa). Therefore, concave-convex portions on the rear surface of a projection PRJ are likely to appear (see FIG. 4).

Also, the adhesive may have a thickness of, for example, about 5 μm to about 100 μm, and an elastic modulus of, for example, about 10 kPa to about 1,000 kPa. As the adhesive is made thin, with the thickness of about 5 μm to about 100 μm, the concave-convex portions on the rear surface of the projection PRJ are more likely to appear.

In one or more aspects, the terms “about,” “substantially,” and “approximately” may provide an industry-accepted tolerance for their corresponding terms and/or relativity between items, such as a tolerance of ±1%, ±5%, or ±10% of the actual value stated, and other suitable tolerances.

As shown in FIG. 4, when the back-grind tape BGT is attached to the wafer 123, the back side (the opposite surface to the surface on which the adhesive layer is formed) of an attachment surface of the back-grind tape BGT is pushed away and protruded by the pillar 122, thereby forming the projection PRJ. Accordingly, the surface roughness of the back-grind tape BGT increases.

Next, in operation S102, the vacuum chuck suctions the wafer 123, and the wafer 123 is fixed to the vacuum chuck. More specifically, as shown in FIG. 5, a vacuum chuck VCK suctions the back-grind tape BGT attached to the first surface SC1 of the wafer 123, and thus, the wafer 123 is suctioned and fixed to the vacuum chuck VCK.

As shown in FIG. 6, when the wafer 123 is suctioned and fixed to the vacuum chuck VCK, the back-grind tape BGT and the pillar 122 are pushed toward the wafer 123 by the projection PRJ of the back-grind tape BGT. Accordingly, the wafer 123 is deformed by stress from the back-grind tape BGT and the pillars 122, and thus, a recessed portion is formed in the first surface SC1. On the other hand, a protruding portion PRT corresponding to the recessed portion of the first surface SC1 is formed on the second surface SC2 opposite to the first surface SC1.

Next, in operation S103, a grinding wheel GWL makes the wafer 123 thinner. More specifically, as shown in FIG. 7, the grinding wheel GWL makes the wafer 123 thinner by back-grinding the second surface SC2 of the wafer 123. Therefore, relatively, the surface roughness of the second surface SC2 of the wafer 123 may be less than the surface roughness of the first surface SC1 thereof.

As shown in FIG. 8, the protruding portion PRT of the second surface SC2 is removed by back-grinding the wafer 123. Accordingly, the thickness of the wafer 123 decreases.

Next, in operation S104, the second attachment device attaches a dicing tape to the surface of the wafer 123 on the opposite side from the surface to which the back-grind tape is attached. Since processes from attaching the dicing tape to the wafer 123 to dicing the wafer 123 are the same as those in the related art, the illustrations thereof are omitted.

Next, in operation S105, the first attachment device detaches the back-grind tape of the wafer 123. As shown in FIG. 9, the vacuum chuck VCK moves in a direction away from the wafer 123 while suctioning the back-grind tape BGT, thereby peeling the back-grind tape BGT off the wafer 123.

Next, in operation S106, the dicing device dices the wafer 123 into dies. As used herein, a die formed by dicing the wafer 123 is referred to as the die body 121. Also, the die body 121 and the pillars 122 together are referred to as the die 120.

Next, in operation S107, the die 120 is mounted on the substrate 110. Specifically, as shown in FIG. 10, the sealing device places the die 120 at a certain location on the substrate 110.

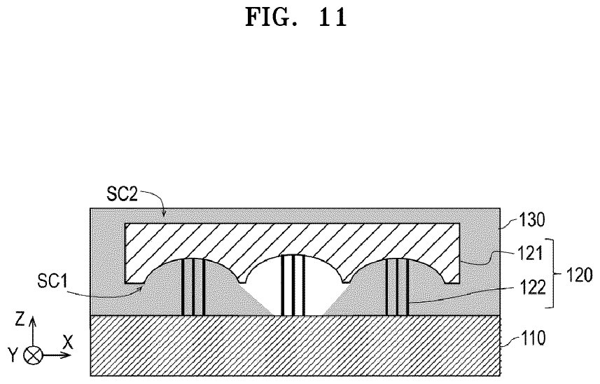

Next, in operation S108, the sealing device seals the die 120. As shown in FIG. 11, the sealing device supplies an underfill material onto the substrate 110. The underfill material fills spaces above the die 120 and around the die 120. Also, the underfill material permeates through the gap between the substrate 110 and the die body 121 while being pressed.

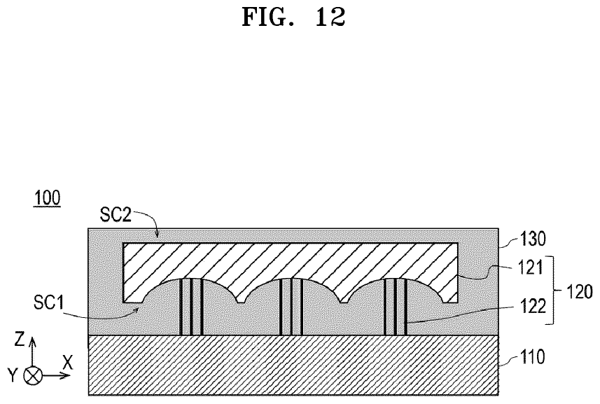

As shown in FIG. 12, the underfill material fills the gap between the substrate 110 and the die body 121. The sealing device cures the underfill material by heating a stack that includes the substrate 110, the die 120, and the sealing member 130, for example, to a temperature higher than a curing temperature of the underfill material. Accordingly, the semiconductor package 100 is formed.

In the embodiment, the gap between the substrate 110 and the die body 121 in a region having the pillar 122 is greater than the gap between the substrate 110 and the die body 121 in a region having no pillar 122. Therefore, compared to the related art, the gap between the substrate 110 and the die body 121 in the region having the pillars 122 increases, which makes it easier for the underfill material to enter the gap. As a result, the formation of voids and other defects in the sealing member 130 is suppressed.

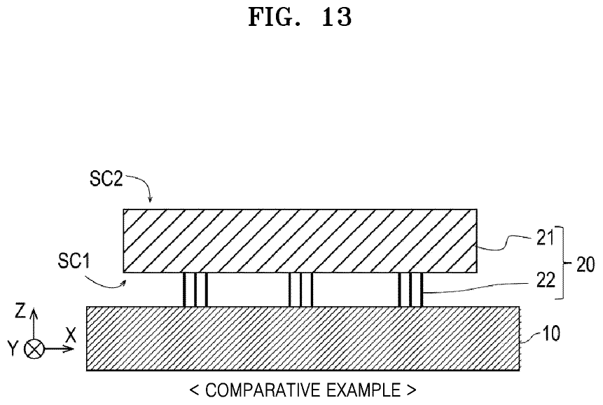

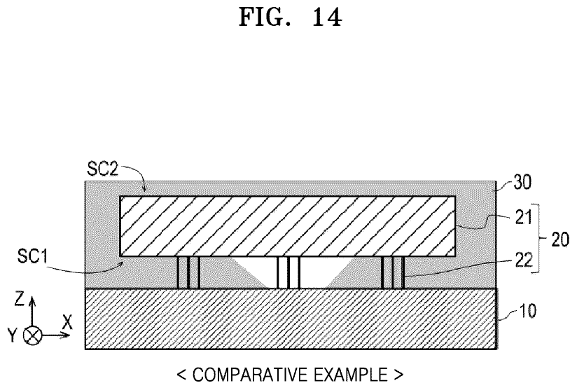

FIGS. 13 to 15 are schematic views illustrating a method of sealing a die in a method of manufacturing a semiconductor package, according to the related art, as a comparative example. In the comparative example, a die body 21 has a uniform thickness and has no concave-convex portion on a first surface SC1 thereof. The sealing device seals a die 20. Specifically, as shown in FIGS. 13 and 14, the sealing device places the die 20 at a certain location on the substrate 10 and supplies an underfill material as a sealing member 30 onto the substrate 10. The underfill material fills spaces above the die 20 and around the die 20. Also, the underfill material permeates through the gap between the substrate 10 and the die body 21 while being pressed. However, due to the narrow gap between the substrate 10 and the die body 21, the underfill material may not fill the gap, especially spaces around a pillar 22 or a central region of the gap.

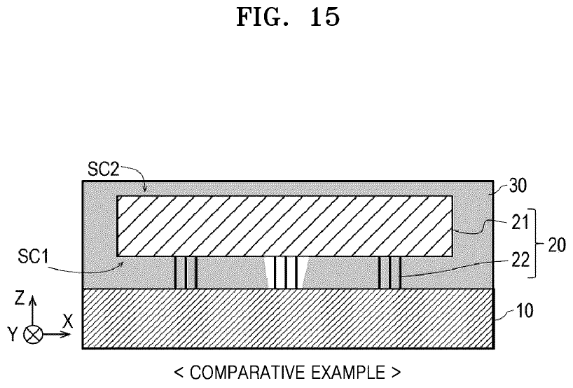

As shown in FIG. 15, the sealing device cures the sealing member 30 by heating a stack that includes the substrate 10, the die 20, and the sealing member 30, for example, to a temperature higher than the curing temperature of the underfill material. A region of the gap between the substrate 10 and the die body 21, which is not filled with the underfill material, may form a void, which may cause a defect in the formation of the sealing member 30.

The semiconductor package 100 according to the embodiment described above exhibits the following specific effects.

The gap between the substrate 110 and the die body 121 in the region having the pillar 122 is formed to be greater than the gap between the substrate 110 and the die body 121 in the region having no pillar 122. Therefore, compared to the related art, the gap between the substrate 110 and the die body 121 in the region having the pillars 122 increases, which makes it easier for the underfill material to enter the gap.

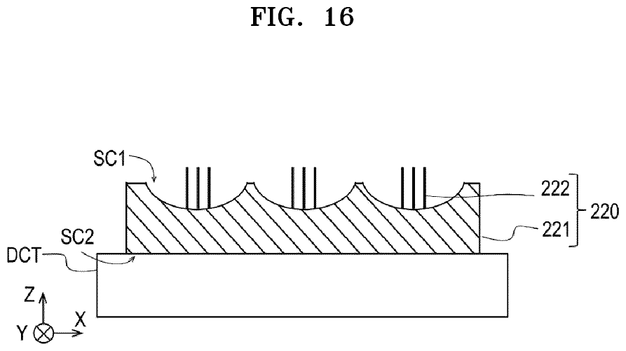

In a second embodiment, a process of picking up a die in face-up mounting is described. Hereinafter, the process of picking up a die, according to the embodiment, is described in detail with reference to FIGS. 16 to 18. FIGS. 16 to 18 are schematic views illustrating a process of picking up a die, according to the second embodiment.

A semiconductor manufacturing apparatus according to the embodiment includes at least a die holding unit, an image capturing unit, a positioning unit, and a pick-up unit (not all shown).

First, as shown in FIG. 16, the die holding unit holds a die 220 in a face-up position, to which a dicing tape DCT is attached, on a stage (not shown). The image capturing unit captures an image of the die 220 on the stage. The positioning unit obtains the information about the position of the die 220 on the stage on the basis of the captured image of the die 220.

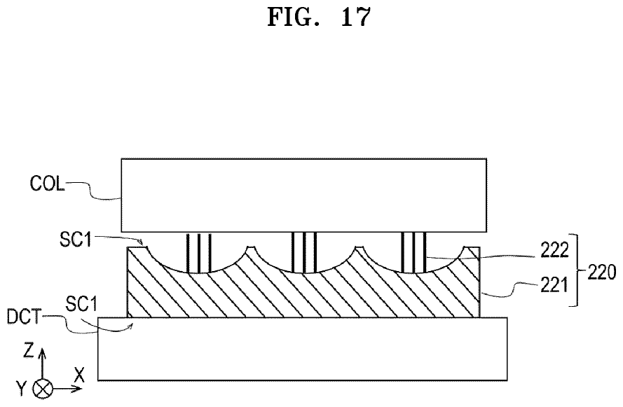

Next, as shown in FIG. 17, the pick-up unit moves a collet COL above the die 220 on the basis of the information about the position of the die 220, and then lowers the collet COL to a pick-up position just above the die 220.

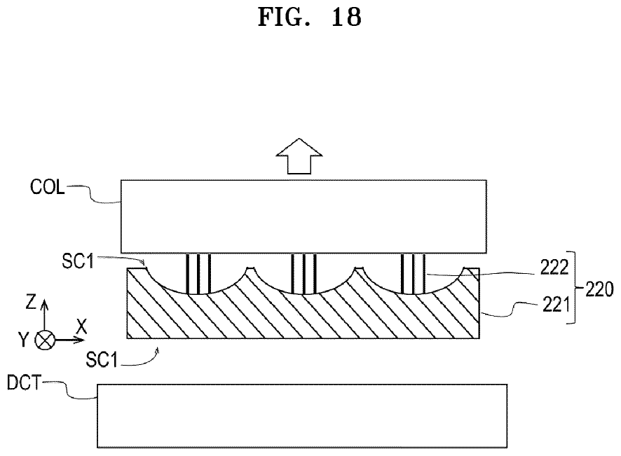

Then, as shown in FIG. 18, the pick-up unit applies negative pressure to the die 220 by using the collet COL and suctions the die 220. In the embodiment, since the die 220 has a concave-convex portion on a first surface SC1 due to a pillar 222, air leakage from a space between the collet COL and the die 220 may be suppressed when the collet COL suctions the die 220. Therefore, the pick-up unit may pick up the die 220, on the first surface SC1 having the pillar 222.

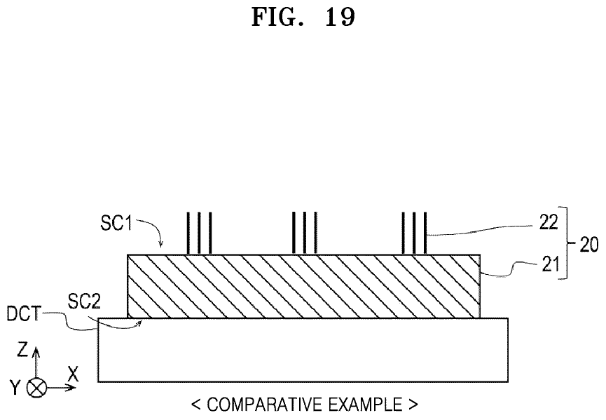

FIGS. 19 to 21 are schematic views illustrating a pick-up process when using a die according to the related art, as a comparative example. In the comparative example, the die body 21 has a uniform thickness and has no concave-convex portion on the first surface SC1 thereof.

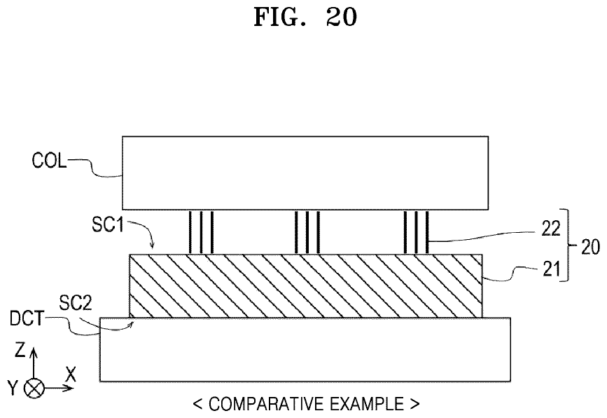

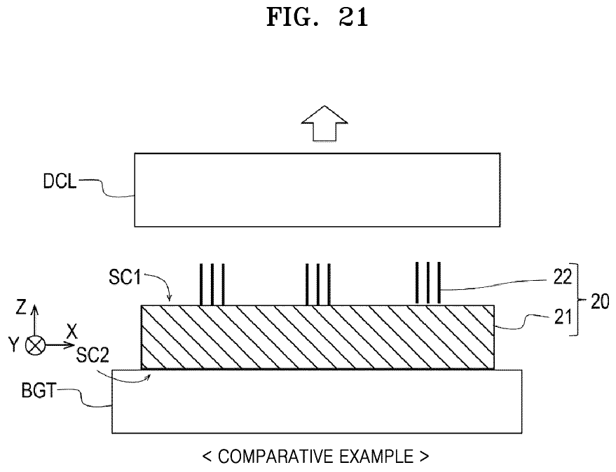

As shown in FIG. 19, the die holding unit holds the die 20 in a face-up position, to which the dicing tape DCT is attached, on the stage (not shown). As shown in FIG. 20, the pick-up unit moves the collet COL to the pick-up position just above the die 20 on the basis of the information about the position of the die 20. As shown in FIG. 21, the die body 21 does not have a concave-convex portion on the first surface SC1 thereof in the comparative example. Accordingly, even when negative pressure is applied to the die 20, air leaks from the space between the collet COL and the die 20, and thus, the collet COL may not suction the die 20. Therefore, the pick-up unit may not pick up the die 20.

The die is manufactured by the process shown in FIGS. 3 to 12 in the method of manufacturing the semiconductor package 100. FIG. 22 is a schematic view based on scanning electron microscope (SEM) images of the manufactured die. The maximum value and the minimum value of the thickness of the die body 121 are 56.2 μm and 37.0 μm, respectively.

Also, in a region in which a number of pillars 122 are densely arranged on the first surface SC1 of the die body 121, the die body 121 has a smaller thickness than a region in which a number of pillars 122 are less densely arranged. The thickness of the die body 121 changes continuously according to the sparseness and denseness of the number of pillars 122 on the first surface SC1.

The semiconductor package 100 has been described above in terms of the main configuration when describing features of the embodiment. The semiconductor package 100 is not limited to the configuration described above, and may be modified in various ways within the scope of the claims. Also, this does not exclude the configuration of general dies and semiconductor packages.

In addition, the first embodiment shows an example of forming the concave-convex portions based on the pillars on the first surface SC1 of the die, but the concave-convex portions may also be formed on the wafer prior to the dicing.

While the inventive concept has been particularly shown and described with reference to embodiments thereof, it will be understood that various changes in form and details may be made therein without departing from the spirit and scope of the following claims.

What is claimed is:

1. A semiconductor package comprising:
a die; and
a plurality of pillars disposed on one surface of the die,
wherein a thickness of the die corresponding to a region having the plurality of pillars on the one surface of the die is less than a thickness of the die corresponding to a region without the plurality of pillars on the one surface of the die.

2. The semiconductor package of claim 1, wherein, in a region of the one surface of the die in which the plurality of pillars are densely arranged, the die has a smaller thickness than other regions of the one surface of the die in which the plurality of pillars are less densely arranged.

3. The semiconductor package of claim 2, wherein the thickness of the die changes continuously along the one surface of the die according to denseness of the number of pillars on the one surface of the die.

4. The semiconductor package of claim 1, wherein a difference between a maximum value and a minimum value of a thickness of the die is greater than or equal to 15 μm.

5. The semiconductor package of claim 1, wherein the die comprises a bridge die configured to connect two different internal dies to each other.

6. The semiconductor package of claim 1, further comprising:
a substrate connected to the die via the plurality of pillars; and
a sealing member configured to seal the die above the substrate.

7. The semiconductor package of claim 6, wherein the die is flip-chip bonded to the substrate via the plurality of pillars.

8. The semiconductor package of claim 6, wherein a thickness of the sealing member between the substrate and the region having the plurality of pillars on the one surface of the die is greater than a thickness of the sealing member between the substrate and the region without the plurality of pillars on the one surface of the die.

9. The semiconductor package of claim 6, wherein the sealing member surrounds the plurality of pillars between the substrate and the die.

10. The semiconductor package of claim 1, wherein the plurality of pillars comprise a conductive material.

11. A semiconductor package comprising:
a substrate;
a die comprising a plurality of pillars disposed on one surface thereof, the die being flip-chip bonded to the substrate via the plurality of pillars; and
a sealing member configured to seal the die and the plurality of pillars above the substrate,
wherein a thickness of the die corresponding to a region having the plurality of pillars on the one surface of the die is less than a thickness of the die corresponding to a region without the plurality of pillars on the one surface of the die, and
a thickness of the sealing member overlapping the region having the plurality of pillars on the one surface of the die is greater than a thickness of the sealing member overlapping the region without the plurality of pillars on the one surface of the die.

12. The semiconductor package of claim 11, wherein surface roughness of the one surface of the die is greater than surface roughness of a surface of the die opposite to the one surface of the die.

13. A semiconductor package comprising:
a die; and
a plurality of pillars disposed on one surface of the die,
wherein the die includes a plurality of recesses in which the plurality of pillars are disposed, respectively.

14. The semiconductor package of claim 13, wherein the plurality of pillars include a first group of pillars and a second group of pillars disposed in a first recess and a second recess, respectively, among the plurality of recesses.

15. The semiconductor package of claim 14, wherein intervals of pillars included in each of the first and second groups of pillars is less than a distance between the first and second groups of pillars.

16. The semiconductor package of claim 13, wherein, within a group of pillars disposed in one of the plurality of recesses, intervals of pillars in some regions differ from intervals of pillars in other regions.

17. The semiconductor package of claim 13, wherein, in a region of the one surface of the die in which the plurality of pillars are densely arranged, the die has a smaller thickness than other regions of the one surface of the die in which the plurality of pillars are less densely arranged.

18. The semiconductor package of claim 13, further comprising:
a substrate connected to the die via the plurality of pillars; and
a sealing member configured to seal the die above the substrate.

19. The semiconductor package of claim 18, wherein the die is flip-chip bonded to the substrate via the plurality of pillars.

20. The semiconductor package of claim 13, wherein a thickness of the die corresponding to a region having the plurality of pillars on the one surface of the die is less than a thickness of the die corresponding to a region without the plurality of pillars on the one surface of the die.
